(19) United States
(12) Patent Application Publication
(10) Pub. No.: US 2006/0175642 A1
(43) Pub. Date: Aug. 10, 2006

(54) Semiconductor device and method of manufacturing the same

(75) Inventors: Aki Dote, Kawasaki (JP); Genichi Komuro, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/138,448

(22) Filed: May 27, 2005

(30) Foreign Application Priority Data
Feb. 9, 2005 (JP) 2005-033502

(51) Int. Cl. H01L 29/94

(52) U.S. Cl. 257/295

(57) ABSTRACT

In a ferroelectric capacitor structure 30 in which a lower electrode and an upper electrode are coupled capacitively with each other through a ferroelectric film, when the upper electrode is formed into a two-layer structure in which a conductive oxide film and an oxidation-resistant metal film are stacked, a protective film is formed on the oxidation-resistant metal film, and the upper electrode of which upper surface alone is covered with the protective film is pattern formed.

### CROSS-REFERENCE TO RELATED APPLICATIONS

This application is based upon and claims the benefit of priority from the prior Japanese Patent Application No. 2005-033502, filed on Feb. 9, 2005, the entire contents of which are incorporated herein by reference.

### BACKGROUND OF THE INVENTION

1. Field of the Invention

This invention relates to a semiconductor device having a dielectric capacitor structure in which a dielectric film is sandwiched between a lower electrode and an upper electrode and a method of manufacturing the same, and is especially preferable to be applied to a ferroelectric memory of which dielectric capacitor structure has a dielectric film made of a material including a ferroelectric.

2. Description of the Related Art

Conventionally, as a nonvolatile memory in which stored information is not erased even if an power supply is turned off, a flash memory and a ferroelectric memory (FeRAM: Ferro-electric Random Access Memory) are known.

The flash memory has a floating gate embedded in a gate insulating film of an insulated-gate field effect transistor (IGFET) and stores the information by storing charges representing stored information in the floating gate. It is necessary to apply a tunnel current passing through the insulating film for writing and erasing the information, thus a relatively high voltage is required.

The FeRAM stores information, utilizing a hysteresis characteristic of the ferroelectric. In a ferroelectric capacitor structure having a ferroelectric film as a pair of dielectrics between electrodes, the polarization is generated according to an applied voltage between electrodes, and there is a spontaneous polarization even when the applied voltage is turned off. When inverting the polarity of the applied voltage, the polarity of the spontaneous polarization is also inverted. By detecting the spontaneous polarization, the information can be read out. The FeRAM has an advantage that can operate in lower voltage compared with the flash memory and write at high speed with saved power. A logic merged chip (SOC: System On Chip) in which the FeRAM is introduced into a conventional logic technology is considered as applications for an IC card or the like.
[Patent document 1] Japanese Patent Application Laid-open No. Hei 10-41478
[Patent document 2] Japanese Patent Application Laid-open No. 2002-210796

### SUMMARY OF THE INVENTION

In a FeRAM, there is a problem that a ferroelectric film tends to deteriorate by hydrogen and the like generated various processes after forming a ferroelectric capacitor structure. Therefore, in order to block the ferroelectric film from the hydrogen and the like, a technology forming an upper electrode by using a conductive oxide, for example, iridium oxide (IrOx) and the like is thought out.

However, by using the conductive oxide as materials of the upper electrode, it is considered that oxide thereof contributes the block for the hydrogen and the like, but on the other hand, a problem that a base film of a connection plug placed just above the upper electrode (Ti, TiN or the like) is oxidized by oxygen discharged to incur the increase of a contact resistance. Hence, a technology forming an oxidation-resistant metal film made of iridium (Ir), platinum (Pt) or the like on the conductive oxide to prevent the oxidation of the base film is thought out.

However, even when the upper electrode is allowed to be a two-layer structure composed of the conductive oxide film and the oxidation-resistant metal film as described above, the following problems occur. When the FeRAM is fabricated, a heating treatment (an annealing treatment) is required to be performed after pattern-forming the upper electrode to recover damages of the ferroelectric film generated when forming a stacked film to be the upper electrode on the ferroelectric film, or when pattern-forming the upper electrode by processing the stacked film. Due to the annealing treatment, protrusions (hillocks) are generated on the oxidation-resistant metal film, which causes the surface roughness on the upper electrode. This surface roughness becomes a main cause incurring a patterning failure or a contact failure of the upper electrode when forming a connection hole in the upper electrode.

The present invention is made in view of the above problems, and the object thereof is to provide a semiconductor device and a method of manufacturing the same which secures an excellent capacitor characteristic by forming an upper electrode of a capacitor structure into a two-layer structure composed of a conductive oxide film and an oxidation-resistant metal film, and which realizing a highly reliable capacitor structure by suppressing the surface roughness in the upper electrode.

A semiconductor device of the present invention includes a semiconductor substrate and a ferroelectric capacitor structure formed above the semiconductor substrate, in which a ferroelectric film is sandwiched between a lower electrode and an upper electrode. The upper electrode is allowed to have at least a stacked structure composed of a first conductive film made of a conductive oxide and a second conductive film made of an oxidation-resistant metal, in which a protective film made of an insulating material is formed so as to cover only an upper surface of the second conductive film.

A method of manufacturing a semiconductor device of the present invention is the method of manufacturing the semiconductor device including a semiconductor substrate and a ferroelectric capacitor structure formed above the semiconductor substrate, in which a ferroelectric film sandwiched between a lower electrode and an upper electrode, having the steps of: forming at least a stacked film composed of first conductive film made of an inductive oxide and a second conductive film made of an oxidation-resistant metal on the lower electrode through the ferroelectric film; forming a protective film made of an insulating material on the stacked film; pattern-forming the upper electrode into the state such that only upper surface thereof is covered with the protective film by processing at least the protective film and the stacked film into an electrode shape; and performing a heating treatment in a state such that the protective film is formed on the upper electrode.

### BRIEF DESCRIPTION OF THE DRAWINGS

FIG. 1A to FIG. 1E are schematic sectional views showing a method of manufacturing a ferroelectric memory according to a first embodiment in order of process;

FIG. 2A to FIG. 2D are schematic sectional views showing the method of manufacturing the ferroelectric memory according to the first embodiment in order of process, followed by FIGS. 1;

FIG. 3A and FIG. 3B are schematic sectional views showing the method of manufacturing the ferroelectric memory according to the first embodiment in order of process, followed by FIGS. 2;

FIG. 4A to FIG. 4D are schematic sectional views showing a method of manufacturing a ferroelectric memory according to a second embodiment in order of process;

FIG. 5A to FIG. 5D are schematic sectional views showing the method of manufacturing the ferroelectric memory according to the second embodiment in order of process, followed by FIGS. 4;

FIG. 6A to FIG. 6C are schematic sectional views showing the method of manufacturing the farroelectric memory according to the second embodiment in order of process, followed by FIGS. 5; and

FIG. 7A and FIG. 7B are schematic sectional views showing the method of manufacturing the ferroelectric memory according to the second embodiment in order of process, followed by FIGS. 6.

### DETAILED DESCRIPTION OF THE PREFERRED EMBODIMENTS

—Basic Gist of the Present Invention—

In a FeRAM, it is indispensable that an annealing treatment for recovering a capacitor characteristic is performed after a ferroelectric capacitor structure is formed (preferably just after the formation). The present inventor devised that a protective film made of an insulating material is formed on an oxidation-resistant metal film and the annealing treatment is performed in this state for preventing occurrence of hillocks in the oxidation-resistant metal film caused by the annealing treatment. In this case, a characteristic of a ferroelectric film does not recover when the annealing treatment is performed with the protective film formed so as to cover the whole surface of the upper electrode including the oxidation metal film and the ferroelectric film, therefore, the protective film is required to be formed only on the upper surface of the oxidation-resistant metal film. Thus, by forming the protective film only on an upper surface of the oxidation-resistant metal film and performing the annealing treatment in this state, an excellent characteristic is secured and the occurrence of hillocks on the upper electrode of the capacitor is prevented, as a result, a highly reliable capacitor structure is realized.

As methods of covering the surface of a Pt film with alumina or the like for suppressing the occurrence of hillocks caused by the annealing treatment, there are several well-known examples, however, they are differentiated from the present invention in a manner as follows. In patent document 1, there is some description in which the surface of the Pt film is covered with alumina, SiO or the like, however, the Pt film is a lower electrode of a capacitor.

In addition, in Patent document 2, there is some description in which the occurrence of hillocks is suppressed in an upper electrode of a capacitor made of a Pt film, however, there is not any description or suggestion about the protective film as the present invention.

—Various Specific Embodiments to Which the Present Invention is Applied—

Hereinafter, as various specific embodiments to which the present invention is applied, a structure of a ferroelectric memory will be described with a method of manufacturing the same.

### First Embodiment

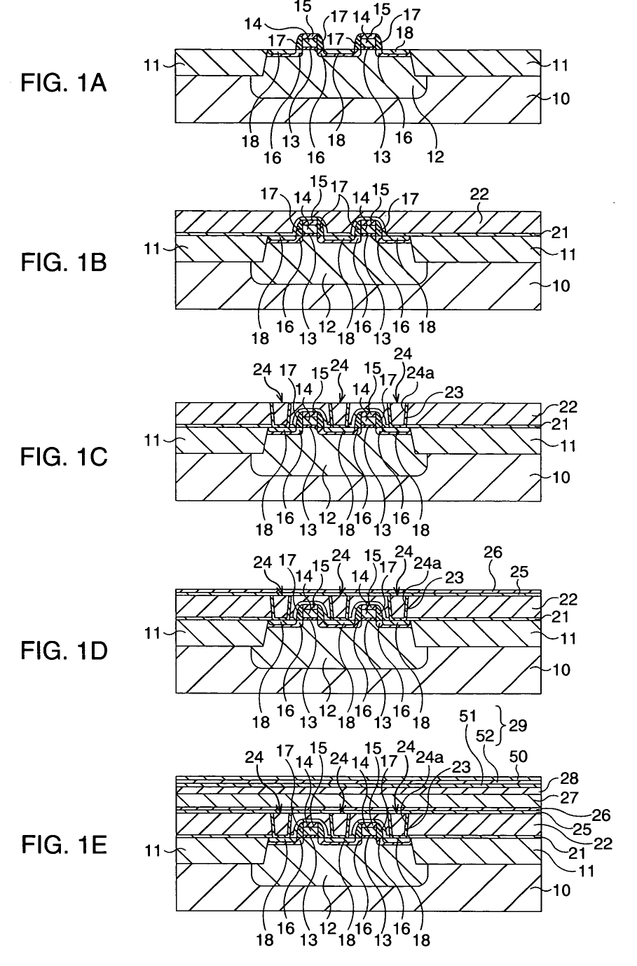

FIGS. 1 to FIG. 3 are schematic sectional views showing a method of manufacturing a ferroelectric memory according to first embodiment in order of process.

First, as shown in FIG. 1A, a MOS transistor 20 functioning as a selection transistor is formed on a silicon semiconductor substrate 10.

Specifically, element isolation structures 11 are formed on a surface layer of the silicon semiconductor substrate (silicon substrate) 10 by means of, for example, a STI (Shallow Trench Isolation) method to demarcate an element active region. It is also preferable that an insulating layer formed on a surface layer of the silicon substrate 10 by a so-called LOCOS (Local Oxidation of Silicon) method is employed as the element isolation structures.

Next, an impurity, boron (B) at this time, is ion-implanted to the element active region in a condition that, for example, a dose amount is 3.0×10¹³/cm², and an acceleration energy is 300 keV to form a well 12.

Next, thin gate insulating films 13 having a film thickness of approximately 3.0 nm are formed in the element active region by a thermal oxidation or the like, a polycrystalline silicon film having a film thickness of approximately 180 nm and, for example, a silicon nitride film having a film thickness of approximately 29 nm are deposited on the gate insulating films 13 by means of a CVD method, and gate electrodes 14 are pattern-formed on the gate insulating films 13 by processing the silicon nitride film, the polycrystalline silicon film and the gate insulating films 13 into electrode shapes by a lithography or a subsequent dry etching. At the same time, cap films 15 made of the silicon nitride film are pattern formed on the gate electrodes 14.

Next, an impurity, arsenic (As) at this time, is ion-implanted to the element active region using the cap films 15 as masks, in a condition that, for example, the dose amount is 5.0×10¹⁴/cm², and the acceleration energy is 10 keV to form so-called LDD (Lightly Doped Drain) regions 16.

Next, a silicon oxide film, for example, is deposited to the whole surface by the CVD method, and sidewall insulating films 17 are formed, allowing the silicon oxide film to remain only on sidewalls of the gate electrodes 14 and the cap films 15 by etching back the silicon oxide film.

Next, an impurity, phosphorus (P) at this time, is ion-implanted to the element active region using the cap films 15 and the sidewall insulating films 17 as masks, in a condition in which impurity concentration becomes higher than the LDD regions, for example, a condition that the dose amount is 5.0×10¹⁴/cm², and the acceleration energy is 13 keV to form source/drain regions 18 overlapped with the LDD regions 16, and the MOS transistor 20 is completed.

Subsequently, as shown in FIG. 1B, a protective film 21 and a first interlayer insulating film 22 of the MOS transistor 20 are formed.

Specifically, the protective film 21 and the first interlayer insulating film 22 are sequentially deposited so as to cover the MOS transistor 20. As the protective film 21, for example, the film made of a silicon oxide film is deposited to have a film thickness of approximately 20 nm by the CVD method. As the first interlayer insulating film 22, a stacked structure is formed, in which a plasma SiO film (film thickness of approximately 20 nm), a plasma SiN film (film thickness of approximately 80 nm) and a plasma TEOS film (film thickness of approximately 1000 nm) are sequentially formed. After stacking layers, the film is polished to be a film thickness of approximately 700 nm by a CMP process.

Subsequently, as shown in FIG. 1C, first plugs 24 connected to the source/drain regions 18 are formed. Specifically, a via hole 24a, for example, having a hole diameter of approximately 0.25 μm and a depth of approximately 0.7 μm is formed by processing the first interlayer insulating film 22 and the protective film 21 by the lithography and the subsequent dry etching until a part of a surface of source/drain region 18 is exposed.

Next, for example, a Ti film (film thickness of approximately 30 nm) and a TiN film (film thickness of approximately 20 nm) are deposited by a sputtering process so as to cover a wall surface of the via hole 24a to form a base film (a glue film) 23 is formed, then, a W-film, for example, is formed to have more than the depth of the via hole 24a, i.e., a film thickness of approximately 800 nm at this time, so as to embed the via hole 24a through the glue film 23 by the CVD method. After that, the W-film and the glue film are polished by the CMP process taking the first interlayer insulating film 22 as a stopper to form the first plug 24 in which the via hole 24a is embedded by ‘W’ (tungsten) through the glue films 23.

Subsequently, as shown in FIG. 1D, an oxidation preventive film 25 and a first capacitor protective film 26 of the first plugs 24 are formed.

Specifically, the oxidation preventive film 25 is formed in order to prevent the first plugs 24 from being oxidized due to a thermal annealing in an oxygen atmosphere when forming a ferroelectric capacitor structure. The oxidation preventive film 25 is allowed to be the stacked structure of, for example, a SiON film (film thickness of approximately 100 nm) and a plasma TEOS film (film thickness of approximately 130 nm).

Next, the first capacitor protective film 26 is formed on the oxidation preventive film 25 in order to protect the lower electrode of the ferroelectric capacitor structure and to improve the crystallinity of the ferroelectric film. The first capacitor protective film 26 is formed using, for example, alumina as a material to have a film thickness of approximately 20 nm by the sputtering process.

Subsequently, as shown in FIG. 1E, a conductive film for lower electrodes 27, a ferroelectric film 28, a conductive film for upper electrodes 29 and a protective film 50 are sequentially formed.

Specifically, at first, the conductive film for lower electrodes 27 is formed by depositing a Pt film, for example, having a film thickness of approximately 150 nm by the sputtering process. Next, the ferroelectric film 28 made of, for example, PZT as being a ferroelectric is deposited on the conductive film for lower electrodes 27 to have a film thickness of approximately 150 nm, for example, by an RF sputtering process. Then, an annealing treatment for crystallizing the ferroelectric film 28 is performed to the ferroelectric film 28. In this case, the annealing treatment is executed at a treatment temperature of 590° C. for 90 seconds in the oxygen atmosphere.

Next, a conductive oxide film 51 and an oxidation-resistant metal film 52 are sequentially stacked on the ferroelectric film 28 to form the conductive film for upper electrodes 29 having two-layer structure. In this case, an IrO₂ film, for example, having a film thickness of 250 nm as the conductive oxide film 52, and a Pt film having a film thickness of approximately 100 nm as the oxidation-resistant metal film 52 are sequentially formed by, for example, a reactive sputtering process to deposition-formed the conductive film for upper electrodes 29. Then, during the formation of the conductive film for upper electrodes 29, for example, after the conductive oxide film 51 is formed, the annealing treatment for crystallizing the ferroelectric film 28 is performed. In this case, the annealing treatment is performed at the treatment temperature of 725° C. for 20 seconds in the oxygen atmosphere. As the conductive oxide film 51, Ir, Ru, RuO₂, SrRuO₃, or other conductive oxides, or the stacked structure of these can be used instead of IrO₂. In addition, as the oxidation-resistant metal film 52, an Ir film and the like can be formed instead of the Pt film.

Next, the protective film 50 is formed on the conductive film for upper electrodes 29 (on the oxidation-resistant metal film 52). The protective film 50 is formed using, for example, alumima as the material by the sputtering process to have a film thickness of approximately 20 nm. As the protective film 50, insulating materials such as SiO₂, SiN, SiON, TiO₂ or the like can be used.

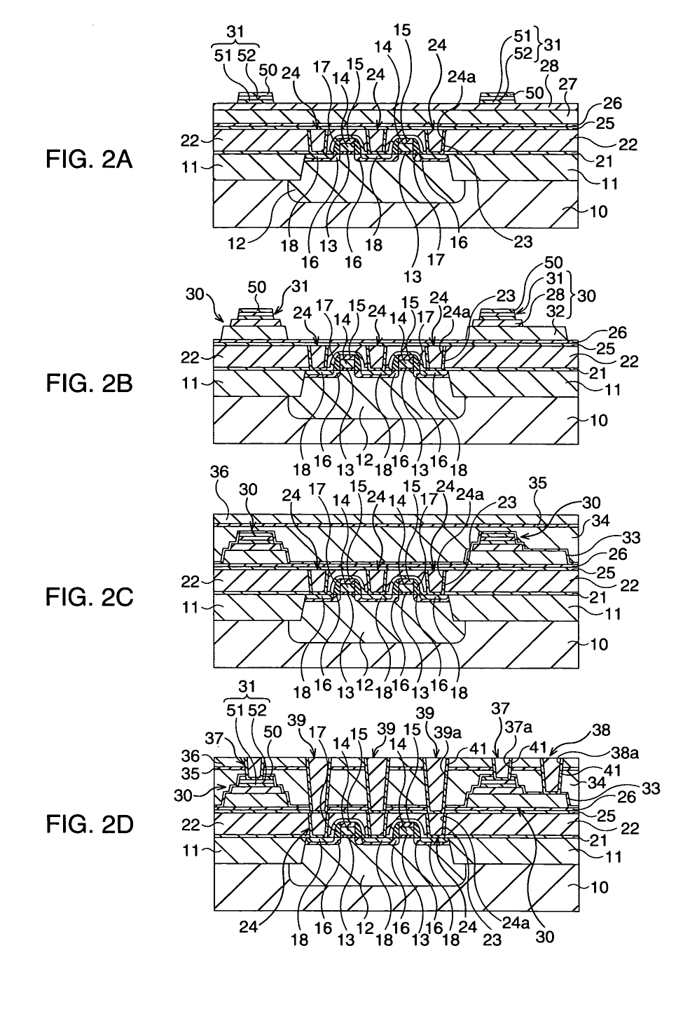

Subsequently, as shown in FIG. 2A, upper electrodes 31 in which only upper surfaces thereof are covered with the protective film 50 are pattern-formed.

Specifically, the protective film 50 and the conductive film for upper electrodes 29 are simultaneously processed into plural electrode shapes by the lithography and the subsequent dry etching to pattern-form plural upper electrodes 31, in which the protective films 50 are formed on the surface thereof, and the conductive oxide films 51 and the oxidation-resistant metal films 52 are stacked thereon. In this case, since the protective film 50 and the conductive film for upper electrodes 29 are processed continuously, the upper electrodes 31 are covered with the protective film 50 only at the surface thereof.

Subsequently, as shown in FIG. 2B, the ferroelectric film 28 and the conductive film for lower electrodes 27 are processed to form a ferroelectric capacitor structure 30.

Specifically, at first, the ferroelectric film 28 is matched with the upper electrode 31 and processed so as to be slightly larger size than the upper electrode 31 by the lithography and the subsequent dry etching.

Next, the conductive film for lower electrodes 27 is matched with the processed ferroelectric film 28 and processed so as to be slightly large size than the ferroelectric film 28 by the lithography and the subsequent dry etching to pattern-form lower electrodes 32. Thereby, the ferroelectric film 28, the upper electrode 31 are sequentially stacked on the lower electrode 32 to complete the ferroelectric capacitor structure 30 in which the lower electrode 32 and the upper electrode 31 are coupled capacitively through the ferroelectric film 28.

In the above case, an example is shown, in which the protective film 50 and the conductive film for upper electrodes 29, the ferroelectric film 28, and the conductive film for lower electrodes 27 are independently processed in three stages, using respective different resist masks, however, it is also preferable that, for example, the protective film 50, the conductive film for upper electrodes 29 and the ferroelectric film 28 are processed at the same time, or the ferroelectric film 28 and the conductive film for lower electrodes 27 are processed at the same time, or the protective film 50, the conductive film for upper electrodes 29, ferroelectric film 28 and the conductive film for lower electrodes 27 are processed all together.

Next, after forming the ferroelectric capacitor structure 30, just after the formation in this case, an annealing treatment is performed for recover damages suffered by the ferroelectric capacitor structure 30 during the formation of the ferroelectric capacitor structure 30 and due to various processes after the formation. In this case, the annealing treatment is performed at the treatment temperature of 650° C. for 60 minutes in the oxygen atmosphere. In the present embodiment, the protective film 50 is formed on the upper electrodes 31, therefore the occurrence of hillocks in the oxidation-resistant metal film 52 during the annealing treatment can be suppressed. In addition, since the protective film 50 is formed so as to cover only the upper surface of the upper electrode 31 (upper surface of the oxidation-resistant metal film 52), there is an advantage that the recovery of characteristic of the ferroelectric film 28 is not inhibited.

Subsequently, as shown in FIG. 2C, a second capacitor protective film 33, a second interlayer insulating film 34, a third capacitor protective film 35 and an oxide film 36 are formed. Specifically, the second capacitor protective film 33, the second interlayer insulating film 34, the third capacitor protective film 35 and the oxide film 36 are sequentially stack-formed so as to cover the ferroelectric capacitor structure 30.

The second capacitor protective film 33 is the film for suppressing the damages suffered by the ferroelectric capacitor 30 due to multi-layer processes after forming the ferroelectric capacitor structure 30 and is formed, for example, using alumina as a material to have a film thickness of approximately 20 nm by the sputtering process. After the second capacitor protective film 33 is formed, an annealing treatment is performed for the purpose of dewatering the second capacitor protective film 33. In this case, the annealing treatment is performed at the treatment temperature of 650° C. for 60 minutes in the oxygen atmosphere.

As the second interlayer insulating film 34, for example, a plasma TEOS film is deposited to have a film thickness of approximately 1400 nm, then polished to be a film thickness of approximately 1000 nm by the CMP process. After the CMP process, for example, a plasma annealing treatment of N₂O is performed for the purpose of dewatering the second interlayer insulating film 34.

The third capacitor protective film 35 is the film for suppressing the damages suffered by the ferroelectric capacitor 30 due to the multi-layer processes after the formation thereof and for improving a moisture resistance of the semiconductor device, and is formed using, for example, alumina as a material to have a film thickness of approximately 50 nm by the sputtering process. As the oxide film 36, for example, a plasma TEOS film is deposited to have a film thickness of approximately 200 nm. The formations of the third capacitor protective film 35 and the oxide film 36 can be omitted, giving priority to simplifying the formation processes.

Subsequently, as shown in FIG. 2D, conductive plugs 37, 38 of the ferroelectric capacitor structure 30 and second conductive plugs 39 connected to the first conductive plugs 24 are respectively formed. First, via holes 37a, 38a to the ferroelectric capacitor structure 30 are formed.

Specifically, a process performed, as the lithography and the subsequent dry etching, to the oxide film 36, the third capacitor protective film 35 the second interlayer insulating film 34, the second capacitor protective film 33 and the protective film 50 until a part of the surface of the upper electrode 31 is exposed, and a process performed to the oxide film 36, the third capacitor protective film 35, the second interlayer insulating film 34, and the second capacitor protective film 33 until a part of the surface of the lower electrode 32 is exposed are executed at the same time to form the via holes 37a 38a having, for example, a diameter of approximately 0.5 μm are simultaneously formed to respective portions. When these via holes 37a, 38a are formed, the upper electrode 31 and the lower electrode 32 become etching stoppers respectively.

Next, an annealing treatment is performed for recover the damages suffered by the ferroelectric capacitor structure 30 by various processes after the ferroelectric capacitor structure 30 is formed. In this case, the annealing treatment is executed at the treatment temperature of 500° C. for 60 minutes in the oxygen atmosphere.

Next, a via hole 39a to the first conductive plug 24 is formed.

Specifically, the oxide film 36, the third capacitor protective film 35, the second interlayer insulating film 34, the second capacitor protective film 33, the first capacitor protective film 26 and the oxidation preventive film 25 are processed by the lithography and the subsequent dry etching until a part of a surface of the first conductive plug 24 is exposed, taking the first conductive plug 24 as the etching stopper to form the via hole 39a having, for example, a diameter of approximately 0.3 μm.

Next, the conductive plugs 37, 38 and the second conductive plug 39 are formed.

First, an RF pre-processing of several dozens nanometer in an usual etching conversion of the oxide film, in this case, the pre-processing corresponding to approximately 10 nm is performed, then, a TiN film, for example, having a film thickness of approximately 75 nm is deposited by the sputtering process so as to cover respective inner wall surfaces of the via holes 37a, 38a and 39a to form base films (glue films) 41. Especially, an upper surface of the oxidation-resistant metal film 52 is allowed to be a flat surface with the occurrence of hillocks being prevented due to the formation of the protective film 50, therefore, a patterning failure of the via hole 37a does not occur and the glue film 41 is formed in the inner wall surface of the via hole 37 including a part of the upper surface of the oxidation-resistant metal film 52 with an excellent covering property. As the glue film, a film of one kind among Ti, TaN and TiAlN, or a stacked film of at least two kinds selected from Ti, TiN, TaN and TiAlN can be formed.

Then, for example, W-films are formed so as to embed the via holes 37a, 38a and 39a through the glue films 41 by the CVD method. After that, the W-films and the glue films 41 are polished by the CMP process, taking the oxide film 36 as the stopper to form the conductive plugs 37, 38 and the second conductive plug 39 in which the via holes 37a, 38a and 39a are embedded by ‘W’ (tungsten) through the glue films 41. The first and second conductive plugs 24, 39 are regarded as a so-called via-to-via structure in which they are electrically connected with each other. By the via-to-via structure, an etching margin for the formation of via hole is widened and an aspect ratio of via hole is alleviated.

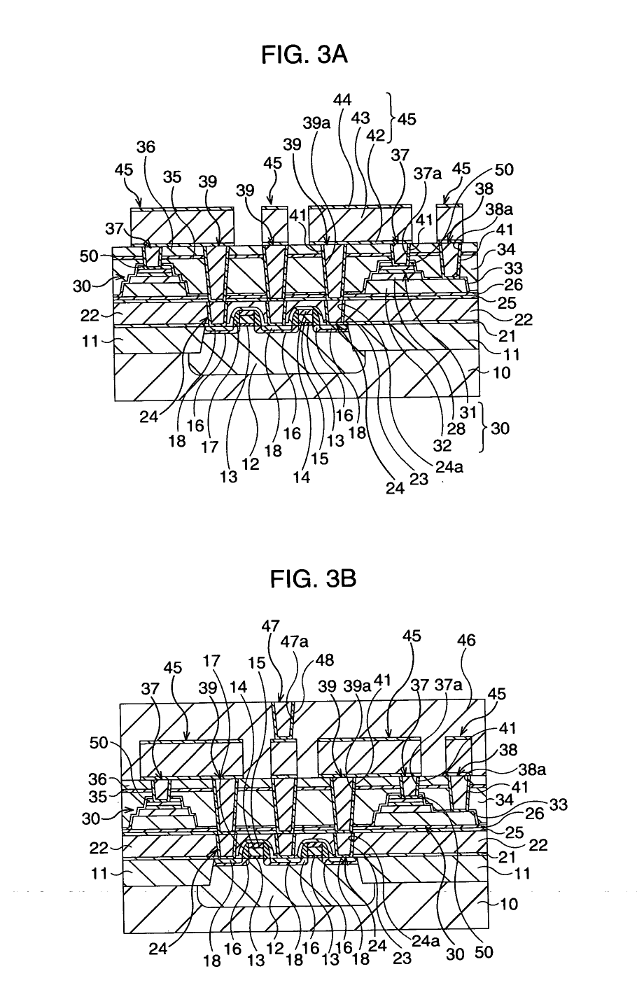

Subsequently, as shown in FIG. 3A, wirings 45 are formed, which are connected to the conductive plugs 37, 38 and the second conductive plug 39 respectively. Specifically, first, a barrier metal film 42, a wiring film 43 and a barrier metal film 44 are deposited to the whole surface by the sputtering process or the like. As the barrier metal film 42, for example, a Ti film (film thickness of approximately 60 nm) and a TiN film (film thickness of approximately 30 nm) are sequentially deposited by the sputtering process. As the wiring film 43, for example, an Al-alloy film (an Al—Cu film in this case) is formed to have a film thickness of approximately 360 nm. As the barrier metal film 44, for example, a Ti film (film thickness of approximately 5 nm) and a TiN film (film thickness of approximately 70 nm) are sequentially deposited by the sputtering process. The structure of the wiring film 43 is the same structure as a logic section other than a FeRAM of the same rule, therefore, there is no problems of the wiring processing or the reliability.

Next, after a SiON film (not shown) is formed as an anti-reflection film, the anti-reflection film, the barrier metal film 44, the wiring film 43 and the barrier metal film 42 are processed into wiring shapes to pattern-form the wirings 45. Instead of forming Al alloy film as the wiring film 43, a Cu film (or a Cu alloy film) may be formed using a so-called damascene method to form a Cu wiring as the wiring 45.

Subsequently, as shown in FIG. 3B, through the formations of a third interlayer insulating film 46, a conductive plug 47 and wirings of further upper layers, the FeRAM is completed.

Specifically, first, the third interlayer insulating film 46 is formed so as to cover the wirings 45. As the third interlayer insulating film 46, a silicon oxide film is formed to have a film thickness of approximately 700 nm, and a plasma TEOS film is formed so that the whole film thickness is approximately 1100 nm, then, a surface thereof is polished by the CMP process to form the film to have a thickness of approximately 750 nm.

Next, the conductive plug 47 connected to the wiring 45 is formed.

The third interlayer insulating film 46 is processed until a part of a surface of the wiring 45 is exposed by the lithography and the subsequent dry etching to form a via hole 47a having a diameter of, for example, approximately 0.25 μm. Next, a base film (a glue film) 48 is formed so as to cover a wall surface of the via hole 47a, then a W-film is formed so as to embed the via hole 47a through the glue film 48 by the CVD method. Then, for example, the W-film and the glue film are polished, taking the third interlayer insulating film 46 as a stopper to form the conductive plug 47 in which the via hole 47a are embedded by ‘W’ (tungsten) through the glue film 48.

After that, wirings of upper layers, processes of forming the interlayer insulating film and the conductive plug are repeated to form, for example, five-layer wiring structure (not shown) including the wirings 45. Then, a first cover film and a second cover film (not shown) are formed. In this example, as the first cover film, for example, an HDP-USG film is deposited to be a film thickness of approximately 720 nm, and as the second cover film, for example, a silicon nitride film is deposited to be a film thickness of approximately 500 nm, respectively. Further, after a contact for leading a pad is formed to the five-layer wiring structure, for example, a polymide film (not shown) is formed and patterned to complete the FeRAM of the present invention.

As described above, according to the present invention, the FeRAM can be obtained, which secures an excellent capacitor characteristic by forming the upper electrode 31 of the capacitor structure 31 into the two-layer structure composed of a conductive oxide film 51 and the oxidation-resistant metal film 52, and which realizing the highly reliable capacitor structure 30 by suppressing the surface roughness in the upper electrode 31.

### Second Embodiment

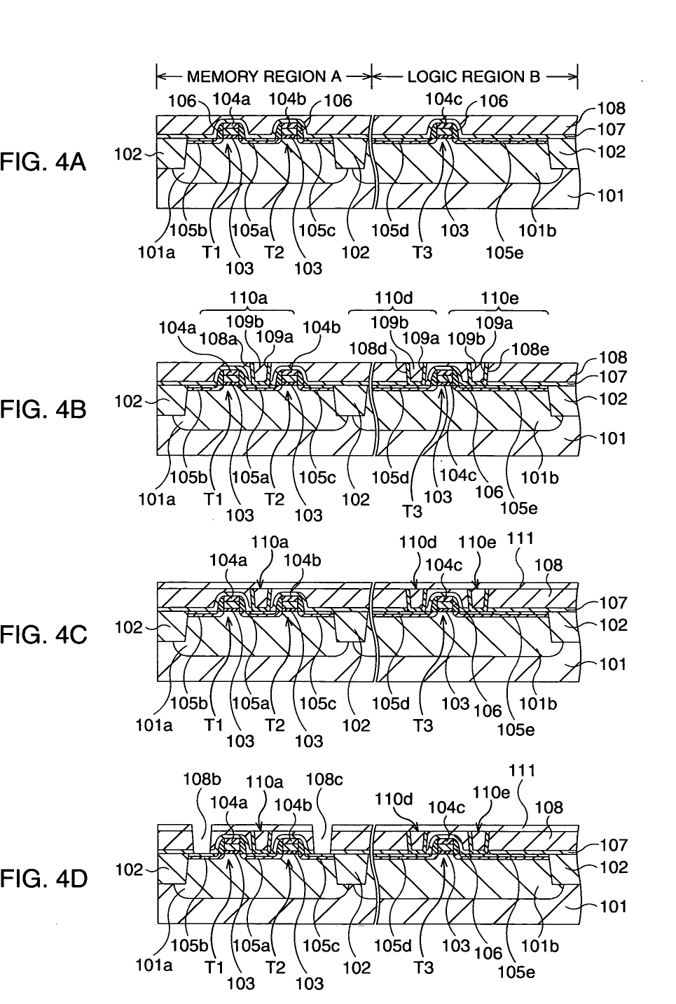

FIGS. 4 to FIGS. 7 are schematic sectional views showing a method of manufacturing a ferroelectric memory according to a second embodiment in order of process. In these drawings, a left side shows a memory cell region A and a right side shows a logic region B, respectively.

First, as shown in FIG. 4A, a MOS transistors T₁, T₂ functioning as selection transistors in the memory cell region A are formed, and a MOS transistor T₃ is formed in a logic region B on the silicon semiconductor substrate 101, respectively.

Specifically, at first, element isolation structures 102 are formed on a surface layer of the silicon semiconductor substrate (silicon substrate) 101 by, for example, an STI method to demarcate element active regions. It is also preferable to employ an insulating film formed on the surface layer of the silicon substrate 101 as the element isolation region by a so-called LOCOS method.

Subsequently, either a p-type impurity or an n-type impurity are selectively introduced into predetermined transistor formation regions of the respective memory cell region A and the logic region B of the silicon substrate 101 to form wells 101a, 101b. In FIG. 4A, the well 101a of the memory cell region A is a p-type, and the well 101b of the logic region B shows a p-type, however, when a CMOS is formed in the logic region B, both n-type and p-type wells are formed. The differentiation of implantation for the n-type well or the p-type well is performed using a resist pattern as a mask.

Furthermore, surfaces of wells 101a, 101b of the silicon substrate 101 are oxidized thermally to form silicon oxide films to be gate insulating films 103.

Next, a polysilicon film is formed on the whole upper surface of the silicon substrate 101. After that, the polysilicon film is processed by a lithography and a subsequent dry etching to form gate electrodes 104a, 104b in the memory cell region A and to form a gate electrode 104c in the logic region B, respectively. These gate electrodes 104a, 104b and 104c are formed on the silicon substrate 101 through the gate insulating films 103.

In the memory cell region A, two gate electrodes 104a, 104b are formed in parallel on one well 101a, and these gate electrodes 104a, 104b compose a part of a word line.

Next, in the memory cell region A, an n-type impurity, for example, phosphorus (P) in this case, is ion implanted to both sides of the gate electrodes 104a, 104b in the P-type well 101a to form n-type impurity diffusion regions 105a to 105c to be sources/drains. At the same time of this, the n-type impurity is also ion implanted to the p-type well 101b in the logic region B to form n-type impurity diffusion regions 105d, 105e to be sources/drains.

In the n-type well of the logic region B (not shown), a p-type impurity, for example, boron (B) in this case, is ion implanted to both sides of a gate electrode (not shown) to form p-type impurity diffusion regions. The differentiation for implanting the p-type impurity or the n-type impurity is performed using a resist pattern.

Next, after a insulating film, for example, a silicon oxide film is formed on the whole surface of the silicon substrate 101 by a CVD method, the insulating film is etched back to be left at both side portions of the gate electrode 104a, 104b, and 104c as sidewall insulating films 106a.

Next, a n-type impurity is ion implanted to the n-type impurity diffusion regions 105a to 105c again, using the gate electrodes 104a, 104b, 104c and the sidewall insulating films 106 as masks, to form high-concentration impurity regions for the n-type impurity diffusion regions 105a to 105c respectively. After that, a p-type impurity is ion implanted to the p-type impurity diffusion regions (not shown) again to form the high-concentration impurity regions.

In one well 101a of the memory cell region A, the n-type impurity diffusion region 105a between the two gate electrodes 104a and 104b is electrically connected to a bit line described later, and the n-type impurity diffusion regions 105b, 105c of both sides of the well 101a are electrically connected to a lower electrode of a capacitor described later.

According to the above processes, the two MOS transistors T₁, T₂ are formed, which have gate electrodes 104a, 104b and n-type impurity diffusion regions 105a to 105c of a LDD structure in the well 101a of the memory cell region A, sharing one n-type impurity diffusion region 105a. In the logic region B, the n-type MOS transistor T₃ is formed, which has a gate electrode 104c and the n-type impurity diffusion regions 105d, 105e at the p-type well 101b. In addition, a p-type MOS transistor is formed at the n-type well (not shown) in the logic region.

A metal silicide layer made of such as cobalt silicide or titan silicide is formed as a contact layer (not shown) on surfaces of the n-type impurity diffusion regions 105a to 105d by a salicide technology.

Next, a silicon oxide film having a thickness of approximately 20 nm and a silicon nitride film (SiN film) having a thickness of approximately 80 nm are formed on the whole surface of the silicon substrate 101 by a plasma CVD method, as a cover insulating film 107 covering the MOS transistors T₁, T₂ and T₃. After that, a silicon oxide film having a film thickness of approximately 1.0 μm is formed on the cover insulating film 107 by the plasma CVD method using a TEOS gas, as a first interlayer insulating film 108 Next, the first interlayer insulating film 108 is heated, for example, in a nitride atmosphere at a normal pressure, at the temperature of 650° C. for 30 minutes, to thereby densify the first interlayer insulating film 108. After that, an upper surface of the first interlayer insulating film 108 is planarized by the chemical mechanical polishing (CMP) process.

Subsequently, as shown in FIG. 4B, conductive plugs 110a, 110d, and 110e are formed.

Specifically, first, the first interlayer insulating film 108 and the cover insulating film 107 are patterned and etched by the lithography and the subsequent dry etching to form a contact hole 108a having a depth reaching the impurity diffusion region 105a in the memory cell region A, at the same time, to form contact holes 108d, 108e on the impurity diffusion regions 105d, 105e composing the MOS transistor T₃ in the logic region B.

Next, a titanium layer having a film thickness of approximately 20 nm and a titanium nitride (TiN) layer having a film thickness of approximately 20 nm are sequentially formed on the upper surface of the interlayer insulating film 108 and inner surfaces of the contact holes 108a, 108d, and 108e as glue films 109a by a sputtering process. And further, tungsten (W) layers 109b are grown on the glue films 109a by the CVD method using WF₆ to completely embed the inside of the contact holes 108a, 108d and 108e.

Next, the tungsten film 109b and the glue film 109a are removed from the upper surface of the first interlayer insulating film 108, polished by the CMP process.

Thus, the tungsten film 109b and the glue film 109a remained in the contact hole 108a are used as the conductive plug 110a electrically connected to the impurity diffusion layer 105a. Also, the tungsten films 109b and the glue films 109a remained in the contact holes 108d. 108e in the login region B are used as the conductive plugs 110d, 110e electrically connected to the impurity diffusion regions 105d, 105e.

Subsequently, as shown in FIG. 4C, an insulative oxygen barrier film 111 is formed.

Specifically, a silicon oxynitride film (SiON film)is formed on the first interlayer insulating film 108 and the conductive plugs 110a, 110d and 110e by the plasma CVD method to have a thickness of approximately 400 nm as the insulative oxygen barrier film 111.

In the present embodiment, the insulative oxygen barrier film 111 is not a multi-layer structure but a single-layer structure as shown in the drawings. Owing to the single-layer insulative oxygen barrier film 111, the conductive plugs 110a, 110d and 110e below are prevented from being oxidized when performing various kinds of anneals described later.

Subsequently, as shown in FIG. 4D, contact holes 108b, 108c are formed.

Specifically, by etching the insulative oxygen barrier film 111, the first interlayer insulating film 108 and the cover insulating film 107, the contact holes 108b, 108c piercing through these insulating layers are formed above the impurity diffusion regions 105b, 105c.

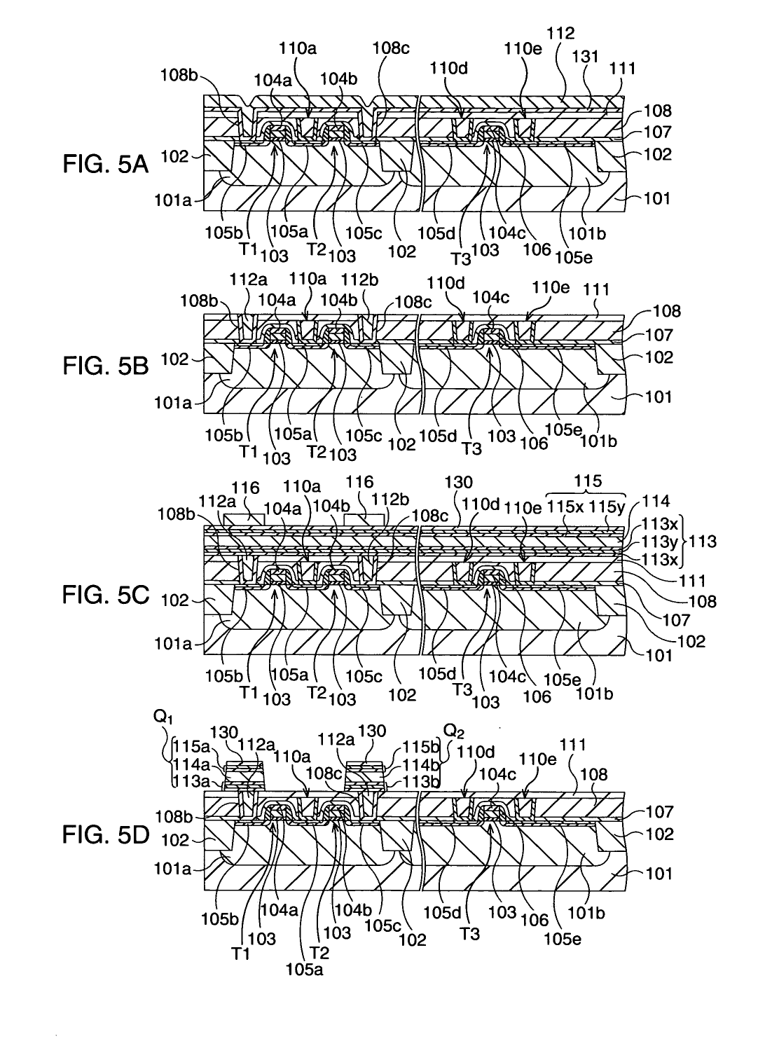

Subsequently, as shown in FIG. 5A, a contact film 131 and a tungsten (W) film 112 are formed. Specifically, a titanium (Ti) film having a film thickness of approximately 20 nm and a titanium nitride (TiN) film having a film thickness of approximately 20 nm are sequentially formed on an upper surface of the insulative oxygen barrier film 111 and inside the contact holes 108b, 108c by the sputtering process as the contact film 131. After that, the tungsten (W) film 112 is formed on the contact film 131 by the plasma CVD process using WF₆ to completely embed the inside of the respective contact holes 108b, 108c.

Subsequently, as shown in FIG. 5B, conductive plugs 112a, 112b are formed.

Specifically, the tungsten film 112 and the contact film 131 are removed from the upper surface of the insulative oxygen barrier film 111, polished by the CMP process. Thus, the tungsten film 112 and the contact film 131 remained in the contact holes 108a, 108c are made to be the conductive plugs 112a, 112b electrically connected to the n-type impurity diffusion regions 105b, 105c, respectively. In this state, the conductive plugs 110a, 110d, 110e made of tungsten are in a state that covered with the insulative oxygen barrier film 111.

Subsequently, as shown in FIG. 5C, various kinds of conductive films 113, 115 and a ferroelectric film 114 as being ferroelectric capacitor structures, and a protective film 130 are formed.

Specifically, first, an iridium (Ir) layer 113x, for example, having a film thickness of approximately 300 nm, a platinum oxide (PtO) layer 113y having a film thickness of approximately 23 nm and a platinum (Pt) layer 113z having a film thickness of approximately 50 nm are sequentially formed by the sputtering process on the conductive plugs 112a, 112b and on the insulative oxygen barrier film 111 as a conductive film for lower electrodes 113.

Before or after the conductive film for lower electrodes 113 is formed, an annealing treatment can be performed to the insulative oxygen barrier film 111, for example, for preventing the film from peeling off. As an annealing treatment, for example, the annealing treatment (RTA) in an argon atmosphere at 600° C. to 750° C. is adopted.

Next, as the ferroelectric film 114, for example, a PZT layer is formed to have a thickness of approximately 140 nm on the conductive film for lower electrodes 113 by the sputtering process. In the present embodiment, a method of manufacturing the ferroelectric film 114 is not limited, and it is preferable that the ferroelectric film 114 is formed by a MOD method, a MOCVD method, sol-gel method or the like. As materials for the ferroelectric film 114, other PZT-type materials such as PLCSZT, PLZT, a Bi-layer structure compound materials such as SrBi₂Ta₂O₉, SrBi₂ (Ta, Nb)₂O₉, or other metal oxide ferroelectrics other than PZT can be used.

Next, a conductive oxidation film 115x and an oxidation-resistant film 115y are sequentially stacked on the ferroelectric film 114 to form a conductive film for upper electrodes 115 having a two-layer structure. In this case, as the conductive oxide film 115x, an IrO₂ film, for example, having a film thickness of approximately 200 nm, and as the oxidation-resistant film 115y, a Pt film having a film thickness of approximately 100 nm are sequentially deposited by, for example, a reactive sputtering process to deposit-form the conductive film for upper electrodes 115. During the formation of the conductive film for upper electrodes 115, for example, after the conductive oxide film 115x is formed, an annealing treatment for crystallizing the ferroelectric film 114 is performed. In this case, the annealing treatment is performed at the treatment temperature of 575° C. in the oxygen atmosphere for 90 seconds. Note that the conductive oxide film 115x can be made of conductive oxides such as Ir, Ru, RuO₂, SrRuO₃ or the like, instead of the IrO₂, or can be made by a stacked structure of these. Additionally, as the oxidation-resistant oxide film 115y, an Ir film or the like can be formed instead of the Pt film.

Next, the protective film 130 is formed on the conductive film for upper electrodes 115 (on the oxidation-resistant metal film 115y). The protective film 130 is formed using, for example, alumina as a material to have a film thickness of approximately 20 nm by the sputtering process. Note that insulating materials such as SiO₂, SiN, SiON, TiO₂ or the like, instead of the alumina, can be used as the protective film 130.

Next, a TiN film and a SiO2 film are sequentially formed as hard masks 116 on the protective film 130. The hard masks 116 are processed so as to be capacitor planar shapes above the conductive plugs 112a, 112b by the lithography and the dry etching.

Subsequently, as shown in FIG. 5D, ferroelectric capacitor structures Q₁, Q₂ are pattern-formed, in which only upper electrodes 115a, 115b are covered with the protective film 130.

Specifically, the protective 130, the conductive film for upper electrodes 115, the ferroelectric film 114 and the conductive film for lower the electrodes 113 in regions not covered with the hard masks 116 are sequentially etched. In this case, the ferroelectric film 114 is etched in an atmosphere including halogen elements by the sputtering reaction. Since the protective film 130 and the conductive film for upper electrodes 115 are continuously processed, the upper electrodes 115a, 115b are formed in a state that the only upper surfaces thereof are covered with the protective film 130.

After that, the hard masks 116 are removed.

According to the above, the ferroelectric capacitor structures Q₁, Q₂ are pattern-formed, which have lower electrodes 113a, 113b formed by processing the conductive film for lower electrodes 113, ferroelectric films 114a, 114b formed by processing the ferroelectric film 114, and the upper electrodes 115a, 115b formed by processing the conductive film for upper electrodes 115 on the insulative oxygen barrier film 111 in the memory cell region A. In one well 101a in the memory cell region A, the lower electrode 113a of the ferroelectric capacitor structure Q₁ is electrically connected to the impurity diffusion region 105b through the conductive plug 112a, and the lower electrode 113b of the ferroelectric capacitor structure Q₂ is connected to the impurity diffusion region 105c through the fifth conductive plug 112b.

Next, in order to recover damages of the ferroelectric film 114 by the etching, an annealing treatment is performed to the ferroelectric capacitor structures Q₁, Q₂. The annealing treatment is performed, for example, in the oxygen atmosphere at the substrate temperature of 650° C. for 60 minutes. In the present embodiment, the protective film 130 is formed on the upper electrodes 115a, 115b, therefore, the occurrence of hillocks in the oxidation-resistant film 115y when performing the annealing treatment can be suppressed. In addition, the protective film 130 is formed so as to cover only the upper surfaces of the upper electrodes 115a, 115b (the upper surfaces of the oxidation-resistant metal film 115y), therefore, the recovery of a characteristic of the ferroelectric film 114 is not inhibited.

Additionally, when the recovery annealing is performed in the atmosphere including oxygen, upper surfaces of the conductive plugs 110a, 110d and 110e not located just below the ferroelectric capacitor structures Q₁, Q₂ are covered with the insulative oxygen barrier film 111, therefore, there is no fear of incurring a contact failure due to the abnormal oxidation of these conductive plugs.

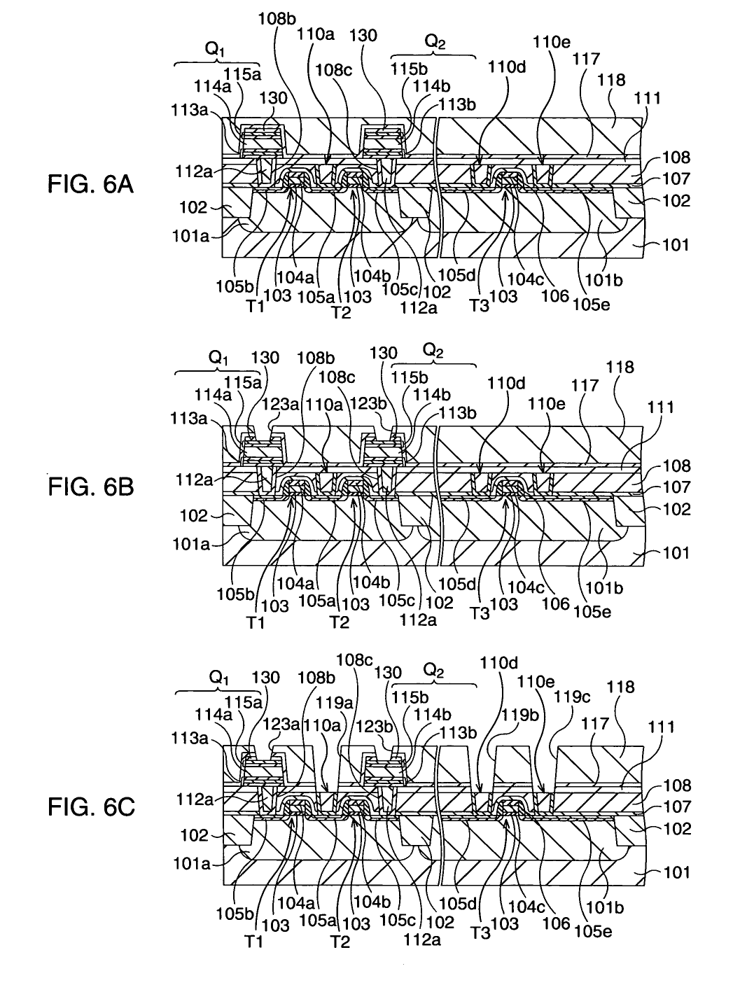

Subsequently, as shown in FIG. 6A, a capacitor protective film 117 and a second interlayer insulating film 118 are sequentially formed. Specifically, first, the capacitor protective film 117 is formed so as to cover the ferroelectric capacitor structures Q₁, Q₂. The capacitor protective film 117 is the film for suppressing damages suffered by the ferroelectric capacitor structures Q₁, Q₂ due to multi-layer processes after forming the ferroelectric capacitor structures Q₁, Q₂, and is formed, for example, using alumina as a material to have a film thickness of approximately 50 nm by the sputtering process. The capacitor protective film 117 can be formed using PZT as the material instead of the alumina. After the capacitor protective film 117 is formed, an annealing treatment for the purpose of dewatering of the capacitor protective film 117 is performed. In this case, the annealing treatment is executed at the treatment temperature of 650° C. in the oxygen atmosphere for 60 minutes.

Next, the second interlayer insulating film 118 is formed on the capacitor protective film 117. As the second interlayer insulating film 118, a silicon oxide film having a film thickness of approximately 1.0 82 m is formed on the capacitor protective film 117 by, for example, the plasma CVD method using the TEOS gas. Further, an upper surface of the second interlayer insulating film 118 is planarized by the CMP process. In this case, the remaining film thickness of the second interlayer insulating film 118 after the CMP process is approximately 300 nm on the upper electrodes 115a, 115b.

Subsequently, as shown in FIG. 6B, holes 123a, 123b are formed above the upper electrodes 115a, 115b of the ferroelectric capacitor structures Q₁, Q₂. Specifically, the second interlayer insulating film 118, the capacitor protective 117 and the protective film 130 are dry etched using a resist pattern (not shown) to form the holes 123a, 123b whereby parts of surfaces of the upper electrodes 115a, 115b are exposed. In this case, the second interlayer insulating film 118, the capacitor protective film 117 and the protective film 130 are etched by using mixed gas of Ar, C₄F₈ and O₂ as an etching gas to expose the parts of surfaces of the upper electrodes 115a, 115b.

After that, in order to recover the ferroelectric film 114 from the damages due to the etching, the annealing treatment is performed to the ferroelectric capacitor structures Q₁, Q₂. The annealing treatment is executed, for example, in the oxygen atmosphere at the substrate temperature of 550° C. for 60 minutes.

Subsequently, as shown in FIG. 6C, via holes 119a, 119b and 119c are respectively formed above the conductive plug 110a in the memory cell region A, and above the conductive plugs 110d, 110e in the logic region B, using a resist pattern (not shown).

These via holes 119a to 119c are formed piercing through the insulative oxygen barrier film 111, the capacitor protective film 117 and the second interlayer insulating film 118, and in the etching thereof, for example, a mixed gas of Ar, C₄F₈ and O₂, or a mixed gas of Ar, CHF₃ and O₂ is used as the etching gas. Then, at the bottoms of respective via holes 119a to 119c, the conductive plugs 110a, 110d, and 110e are exposed respectively.

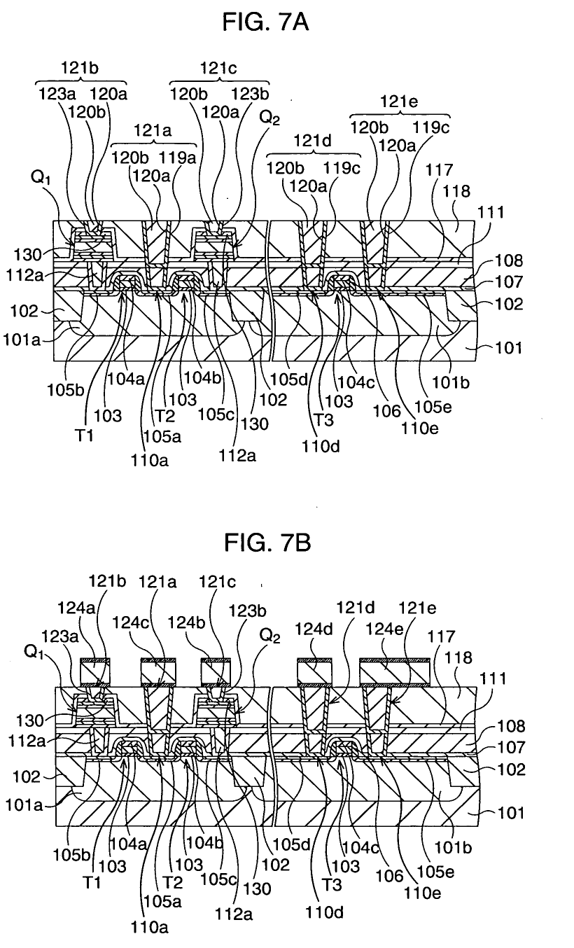

Subsequently, as shown in FIG. 7A, conductive plugs 121a to 121e are formed. Specifically, first, TiN films having film thicknesses of approximately 50 nm as glue films 120a are sequentially formed on the second interlayer insulating film 118 by the sputtering process so as to cover inner wall surfaces of the holes 123a, 123b and via holes 119a to 119c. Note specially that there is no pattering failure of the via holes 123a, 123b and the glue films 120a are formed at inner wall surfaces of the via holes 123a, 123b including the part of upper surface of the oxidation-resistant metal film 115y with an excellent covering property, because the upper surface of the oxidation-resistant metal film 115y is allowed to be a planar surface with the occurrence of hillocks suppressed due to the formation of the protective film 130. The glue films can be formed using one kind among Ti, TaN, and TiAlN instead of TiN, or formed by a stacked film of at least two kinds selected from Ti, TiN.

Next, by growing tungsten films 120b on the glue films 120a by, for example, the CVD method, the inside of the holes 123a, 123b and the via holes 119a to 119c are completely embedded.

Next, the tungsten films 120b and the glue films 120a are removed from the upper surfaces of the interlayer insulating film 118, polished by, for example, the CMP process. Thus, the tungsten films 120b and the glue films 120a remained inside the holes 123a, 123b above the ferroelectric capacitor structures Q₁, Q₂ are allowed to be the conductive plugs 121b, 121c, and the tungsten film 120b and the glue film 120a remained in the via hole 119a above the conductive plug 110a in the memory cell region A is allowed to be the conductive plug 121a. And further, the tungsten films 120b and the glue films 120a remained in the via holes 119b, 119c above the conductive plugs 110d, 110e in the logic region B are allowed to be the conductive plugs 121d, 121e respectively.

Furthermore, the annealing treatment is performed to the second interlayer insulating film 118 in a nitride atmosphere at 350° C. for 120 seconds.

Accordingly, the upper electrodes 115a, 115b of the two ferroelectric capacitor structures Q₁, Q₂ in the memory cell region A are electrically connected to the respective conductive plugs 121b, 121c. The other conductive plugs 121a, 121d, and 121e are electrically connected to the conductive plugs 110a, 110d and 110e.

Subsequently, as shown in FIG. 7B, metal wirings 124a, 124b, 124d, and 124e, and a conductive pad 124c connected to the conductive plug 121a are formed. Specifically, first, multi-layer metal films are formed on the conductive plugs 121a to 121e and on the second interlayer insulating film 118. As the multi-layer metal films, for example, a Ti film having a film thickness of approximately 60 nm, a TiN film having a film thickness of approximately 30 nm, an Al—Cu film having a film thickness of 400 nm, a Ti film having a film thickness of approximately 5 nm and a TiN film having a film thickness of approximately 70 nm are sequentially formed. Next, the multi-layer metal films are processed by the lithography and the dry etching to form the first-layer metal wirings 124a, 124b, 124d, and 124e connected to the conductive plugs 121b to 121e, and the conductive pad 124c connected to the conductive plug 121a.

It is also preferable that an anti-reflection film (not shown) such as a silicon oxynitride film (SiON film) or the like is used to prevent the pattern accuracy from being lowered by the reflection of an exposure light when the multi-layer metal films are patterned.

Then, through the formation of a third interlayer insulating film (not shown) and the like, the FeRAM is completed.

Specifically, the third interlayer insulating film is formed on the second interlayer insulating film 118, the first-layer metal wirings 124a, 124b, 124d and 124e and the conductive pad 124c. After that, a bit line is further connected on the conductive pad 124c through a conductive plug 125a, however, the details thereof are omitted.

When the ferroelectric film 114 is formed by the sputtering process as in the present embodiment, the higher the temperature of the recovery annealing becomes, the better the crystallization of the ferroelectric film 114 becomes, therefore, the recovery annealing is preferable to be performed at the relatively high temperature.

However, when the insulating oxygen barrier film has the multi-layer structure, it becomes evident that the lower electrodes are peeled off due to the high-temperature annealing. Presumably, it occurs because the movements of oxygen atoms in an insulative adhesive layer, for example, made of SiO2 (the most upper film when the insulative oxygen barrier film has the multi-layer structure) become active. As a result, oxygen in the annealing atmosphere reaches the conductive plugs to incur the disadvantage that these tungsten plugs are oxidized and expanded.

Against this backdrop, in the present embodiment, since the insulative oxygen barrier film 111 is formed by the single-layer SiON film, the recovery annealing can be at the high temperature while the peeling-off of the lower electrodes 113a, 113b and the oxidation of respective conductive plugs 112a, 112b are prevented, as a result, the crystallization of the ferroelectric films 114a, 114b can be allowed to be good. Accordingly, the characteristic of the ferroelectric capacitor structures Q₁, Q₂ are improved, and the contact between the respective plugs 112a, 112b and the lower electrodes 114a, 114b are allowed to be good to improve the reliability of the FeRAM.

Such advantages can be also obtained by forming a silicon nitride (SiN) film or an alumina (Al₂O₃) film as the single-layer insulative oxygen barrier film 111. Whereas, the above advantages cannot be obtained by forming an silicon oxide film (SiO₂) film as the insulative oxygen barrier film 111.

As described above, according to the present embodiment, the FeRAM can be obtained, which secures an excellent capacitor characteristic by forming the upper electrodes 115a, 115b of the ferroelectric capacitor structures Q₁, Q₂ to have the two-layer structure composed of the conductive oxide film 115x and the oxidation-resistant metal film 115y, and which realizes in which the highly reliable ferroelectric capacitor structures Q₁, Q₂ by suppressing the surface roughness in the upper electrodes 115a, 115b.

The present invention is not limited to the above-described first and second embodiments. In the present invention, when the upper electrode is allowed to be the two-layer structure composed of the conductive oxide film and the oxidation-resistant metal film, and Ti, TiN, TiAlN, TaN and the like are used as the glue film such as the conductive plug for the electrical connection of the upper electrode, the present invention can be applied all FeRAMs.

According to the present invention, a semiconductor device can be obtained, which secures an excellent capacitor characteristic by forming upper electrodes of capacitor structures to have a two-layer structure composed of a conductive oxide film and an oxidant-resistant metal film, and which realizes a highly reliable capacitor structure by suppressing a surface roughness in the upper electrodes.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A semiconductor device, comprising:
a semiconductor substrate; and
a ferroelectric capacitor structure formed above said semiconductor substrate, in which a ferroelectric film is sandwiched between a lower electrode and an upper electrode, and
wherein the upper electrode is allowed to have a stacked structure at least composed of a first conductive film made of a conductive oxide and a second conductive film made of an oxidant-resistant metal; and
wherein a protective film made of an insulating material is formed so as to cover only an upper surface of the second conductive film.

2. The semiconductor device according to claim 1, wherein the first conductive film is made of iridium oxide.

3. The semiconductor device according to claim 1, wherein the second conductive film is made of iridium and platinum.

4. The semiconductor device according to claim 1, wherein the protective film is made of at least one kind selected from aluminum oxide, silicon oxide, silicon oxynitride and titanium oxide.

5. The semiconductor device according to claim 1, wherein the ferroelectric film is made of at least one kind selected from PZT, SBT and BLT.

6. The semiconductor device according to claim 1, wherein a connection hole exposing a part of a surface of the second conductive film is formed to the protective film, and a conductive material is filled in the connection hole through a base film.

7. The semiconductor device according to claim 6, wherein the base film is made of one kind selected from a group consisting of Ti, TiN, TaN and TiAlN, or a stacked film of at least two kinds selected from the group.

8. The semiconductor device according to claim 1, wherein a conductive plug obtaining an electrical connection of the lower electrode is formed on an upper surface of the lower electrode.

9. The semiconductor device according to claim 1, wherein a conductive plug obtaining an electrical connection of the lower electrode is formed on an bottom surface of the lower electrode.

10. A method of manufacturing a semiconductor device including a semiconductor substrate and a ferroelectric capacitor structure formed above the semiconductor substrate, in which a ferroelectric film is sandwiched between a lower electrode and an upper electrode, comprising the steps of:
forming a stacked film composed of at least a first conductive film made of a conductive oxide and a second conductive film made of an oxidation-resistant metal on the lower electrode through the ferroelectric film;
forming a protective film made of an insulating material on the stacked film;
pattern-forming the upper electrode into a state that only an upper surface thereof is covered with the protective film by processing at least the protective film and the stacked film into an electrode shape; and
performing a heating treatment in a state that the protective film is formed on the upper electrode.

11. The method of manufacturing the semiconductor device according to claim 10, wherein the first conductive film is formed using iridium oxide as a material.

12. The method of manufacturing the semiconductor device according to claim 10, wherein the second conductive film is formed using iridium or platinum as a material.

13. The method of manufacturing the semiconductor device according to claim 10, wherein the protective film is formed using at least one kind selected from aluminum oxide, silicon oxide, silicon oxynitride and titanium oxide as a material.

14. The method of manufacturing the semiconductor device according to claim 10, wherein the ferroelectric film is formed using at least one kind selected from PZT, SBT and BLT as a material.
